(19) United States
(12) Patent Application Publication
(10) Pub. No.: US 2024/0313868 A1
(43) Pub. Date: Sep. 19, 2024

(54) ESTIMATION OF THE CUT-OFF FREQUENCY OF AN ELECTRONIC FILTER

(71) Applicant: Nordic Semiconductor ASA, Trondheim (NO)

(72) Inventor: Ivar LØKKEN, Trondheim (NO)

(73) Assignee: Nordic Semiconductor ASA, Trondheim (NO)

(21) Appl. No.: 18/574,481

(22) PCT Filed: Jun. 29, 2022
(86) PCT No.: PCT/EP2022/067992

§ 371 Date: Dec. 27, 2023

(30) Foreign Application Priority Data
Jun. 30, 2021 (GB) 2109488.3

(51) Int. Cl. H04B 17/11; G01R 27/28; H03H 11/12; H04B 1/40

(52) U.S. Cl. CPC H04B 17/11; G01R 27/28; H03H 11/12; H04B 1/40

(57) ABSTRACT

The cut-off frequency of an electronic filter having a nominal transfer function and a nominal cut-off frequency is estimated by: applying a first signal at a first frequency to an input of the filter while sampling an output of the filter in order to obtain a first magnitude measurement, the first frequency being less than the nominal cut-off frequency; applying a second signal at a second frequency to the input of the filter while sampling the output of the filter in order to obtain a second magnitude measurement, the second frequency being greater than the nominal cut-off frequency; and estimating the cut-off frequency of the filter based on the nominal transfer function, the first magnitude measurement, and the second magnitude measurement.

### FIELD

The present invention relates to the estimation of cut-off frequencies of electronic filters.

### BACKGROUND

Wireless radio-frequency (RF) transceivers such as those used for Bluetooth Low Energy (BLE) communications in low-power Internet-of-Things (IoT) devices—e.g. in wearables or sensors—are continuously being developed to reduce hardware size and improve performance, which competes with the aim of keeping production costs at a minimum.

Such wireless RF transceivers typically include one or more electronic filters, e.g. anti-aliasing filters, in a receive chain thereof in order to aid successful reception of signals by filtering out spurious high and/or low-frequency components of a received signal. Such spurious components may arise as a result of noise and/or jitter, an expected and generally unavoidable characteristic of wireless transmissions.

Electronic filters are generally characterised by a transfer function which indicates the attenuation or gain of a signal at the output of a filter relative to the signal at its input, and can therefore be used to characterise the effect a filter will have on a given input signal. Transfer functions for low-pass and high-pass electronic filters are typically characterised by a cut-off frequency (which is sometimes also referred to as a pole or zero).

In the case of low-pass filters, input frequencies that fall below the cut-off frequency thereof are typically attenuated by very small amounts, if at all, and frequencies that fall above the cut-off frequency of the filter are typically attenuated by greater amounts, with the attenuation increasing as the input frequency moves further away from the cut-off frequency. The opposite effect occurs in the case of high-pass filters.

Electronic filters are typically manufactured with one or more specific cut-off frequencies in mind, depending on the filter's intended function. However, process and temperature variations in filters often cause cut-off frequencies thereof to vary and drift significantly from their intended, or nominal, values. It is important to be able to estimate the actual cut-off frequency of an electronic filter in order to compensate therefor, potentially through calibration of a transceiver.

A prior technique for estimating the cut-off frequency of filters included in receive chains of RF transceivers includes providing a replica filter elsewhere within the transceiver (e.g. a different part of an integrated-circuit (IC) system-on-chip (SoC) or printed circuit board (PCB)). The cut-off frequency of the replica filter can then be estimated by measuring a resistor-capacitor (RC) time constant thereof. The cut-off frequency of the replica filter is, in theory, indicative of the cut-off frequency of the filter included in the receive chain. However, process and temperature variations can limit the accuracy with which a cut-off frequency of a filter in question can be estimated using a replica filter. Furthermore, this technique requires dedicated hardware for the replica filter which consumes extra IC or PCB area as well as increasing the bill-of-materials during manufacture of the transceiver. Additionally, the dedicated hardware required for the replica filter draws additional current when in use, thereby increasing overall power consumption. This can be particularly disadvantageous in battery-powered devices.

Another prior technique for estimating the cut-off frequency of a filter involves applying a frequency sweep to the filter being characterised and measuring the cut-off frequency directly. While this technique may obviate the need for additional dedicated hardware for a replica filter, it has the distinct disadvantage of being very slow: a full frequency sweep requires a large quantity of measurements which take a long time to collect.

### SUMMARY OF THE INVENTION

When viewed from a first aspect, the invention provides a method of estimating a cut-off frequency of an electronic filter having a nominal transfer function and a nominal cut-off frequency, the method comprising:
generating a first and a second modulated synthesised signal by modulating a signal output by a local oscillator with respective first and second modulations;
mixing a radio-frequency continuous-wave signal with the first modulated synthesised signal in order to generate a first signal at a first frequency, the first frequency being less than the nominal cut-off frequency;
mixing the radio-frequency continuous-wave signal with the second modulated synthesised signal in order to generate a second signal at a second frequency, the second frequency being greater than the nominal cut-off frequency;
applying the first signal to an input of the filter while sampling an output of the filter in order to obtain a first magnitude measurement;
applying the second signal to the input of the filter while sampling the output of the filter in order to obtain a second magnitude measurement; and
estimating the cut-off frequency of the filter based on the nominal transfer function, the first magnitude measurement, and the second magnitude measurement.

When viewed from a second aspect, the invention provides a radio transceiver comprising a local oscillator, a transmitter circuit portion, a mixer and an electronic filter having a nominal cut-off frequency and a nominal transfer function, the radio transceiver being configured to:
generate first and second modulated synthesised signals by modulating a signal output by the local oscillator using the transmitter circuit portion with respective first and second modulations;
mix a radio-frequency continuous-wave signal with the first modulated synthesised signal using the mixer in order to generate a first signal at a first frequency, the first frequency being less than the nominal cut-off frequency;
mix the radio-frequency continuous-wave signal with the second modulated synthesised signal using the mixer in order to generate a second signal at a second frequency, the second frequency being greater than the nominal cut-off frequency;
apply the first signal to an input of the filter while sampling an output of the filter in order to obtain a first magnitude measurement;
apply the second signal to the input of the filter while sampling the output of the filter in order to obtain a second magnitude measurement; and
estimate a cut-off frequency of the filter based on the nominal transfer function, the first magnitude measurement and the second magnitude measurement.

Thus it will be seen that, in accordance with the present invention, a cut-off frequency of an electronic filter can be estimated by directly measuring the response of the filter to a specific calibration signal and by using samples taken at only two distinct calibration frequencies. Such an approach can obviate the need to provide a replica circuit as in some prior art as outlined above. This approach may also have the advantage of reducing the time required to estimate the cut-off frequency of a filter over techniques that require measurements over a large range of input frequencies, e.g. by performing a frequency sweep and measuring the cut-off frequency directly. The present invention may thus provide a quick and efficient method for estimating the cut-off frequency of an electronic filter.

Furthermore, the invention offers a particularly beneficial arrangement whereby the first and second signals are generated internally on a device including the filter, rather than requiring e.g. an external test rig to generate these signals. By generating the first and second signals in this manner, the cut-off frequency of the filter can be estimated using minimal extra components. This enables a transceiver including the electronic filter to be kept physically small, as well as reducing a bill-of-materials required to manufacture it. Furthermore, measurements can be taken directly from the filter in question, rather than a replica, thereby increasing the accuracy of an estimate of the cut-off frequency of the filter in question.

The cut-off frequency could be estimated using more than two measurements, but in a set of embodiments, estimating the cut-off frequency of the filter is based on the nominal transfer function and only the first and second magnitude measurements. Estimating the cut-off frequency may thus require no further magnitude measurements.

By mixing the radio-frequency continuous-wave signal with the modulated synthesised signals, each resultant signal (i.e. the first and second signals) may comprise an intermediate-frequency (IF) continuous-wave signal. Thus, in a set of embodiments, the first signal comprises a first intermediate-frequency signal, and the second signal comprises a second intermediate-frequency signal.

In a set of embodiments, the radio-frequency continuous-wave signal has a fixed frequency.

In a set of embodiments, the radio-frequency continuous-wave signal is generated externally to the radio transceiver by a signal generator and received by the transceiver. The radio-frequency continuous-wave signal may be received by an antenna of the transceiver. In preferred embodiments where the radio-frequency continuous-wave signal has a fixed frequency, such an arrangement would still be advantageous over an arrangement in which a test rig was required to generate a signal over a wide range of frequencies. This may reduce the cost and increase the portability of signal generators required to generate the RF CW signal in order to estimate the cut-off frequency of the filter.

In a set of embodiments, the radio transceiver is configured to generate the radio-frequency continuous-wave signal internally based on a signal output by the local oscillator. The generated radio-frequency continuous-wave signal may be fed to an antenna of the transceiver or to circuitry coupled to said antenna. The radio-frequency continuous-wave signal may be generated using a signal converter module that generates, from the local oscillator signal, a test signal comprising a plurality of harmonics of the local oscillator signal, at least one of the plurality of harmonics providing the radio-frequency continuous-wave signal. The at least one of the plurality of harmonics may be isolated using an electronic filter—e.g. a high pass filter, which may comprise a capacitor.

In such embodiments, the need for an external signal generator is obviated, thus allowing the cut-off frequency of the filter to be estimated by the radio transceiver automatically. As well as simplifying the calibration of such devices during production this may open up the possibility of carrying out cut-off frequency estimations while the transceiver is in the field, without external input.

In a set of embodiments, the radio transceiver comprises a transmitter circuit portion and a mixer, wherein:
the first and second modulated synthesised signals are generated by modulating the local oscillator signal using the transmitter circuit portion;
the radio-frequency continuous-wave signal and the first and second modulated synthesised signal are mixed, using the mixer, in order to generate the first signal and the second signal.

By generating the synthesised signal by modulating the local oscillator signal using the transmitter circuit portion, extra components (which increase space and cost) are not required: components already included in the transmitter circuit portion of the transceiver can be used to generate the synthesised signal.

The first frequency may be less than 75% of the nominal cut-off frequency, preferably less than 50% of the nominal cut-off frequency, more preferably less than 25% of the nominal cut-off frequency, yet more preferably less than 10% of the nominal cut-off frequency. By having the first frequency be significantly less than the nominal cut-off frequency of the filter, the frequency response of the filter to the first signal is indicative of a DC-gain of the filter.

The second frequency may be greater than 150% of the nominal cut-off frequency, preferably greater than 200% of the nominal cut-off frequency, more preferably greater than 300% of the nominal cut-off frequency, yet more preferably greater than 500% of the nominal cut-off frequency. By having the second frequency be significantly greater than the nominal cut-off frequency of the filter, the frequency response of the filter to the second signal can be used to estimate the cut-off frequency of the filter when used in conjunction with the frequency response of the filter to the first signal.

In a set of embodiments, the filter comprises a low-pass filter. In other embodiments, the filter comprises a high-pass filter. The filter may comprise an anti-aliasing filter of a radio transceiver. The filter may comprise an n^{th} order Butterworth filter. The filter may comprise a third-order Butterworth filter. The filter may comprise a fourth-order Butterworth filter. The filter may be included in a receiver circuit portion or receive chain of a radio transceiver.

In a set of embodiments, estimating the cut-off frequency is based on a ratio of the second magnitude measurement to the first magnitude measurement.

In a set of embodiments, the first magnitude measurement is obtained by taking a first plurality of samples at an output of the filter while applying the first signal to an input of the filter, and the second magnitude measurement is obtained by taking a second plurality of samples at an output of the filter while applying the second signal to an input of the filter. The first magnitude measurement may be obtained by calculating a first root-mean-squared (RMS) value from the first plurality of samples, and the second magnitude measurement may be obtained by calculating a second root-mean-squared value from the second plurality of samples. By taking a plurality of samples while applying each of the respective first and second signals to an input of the filter and calculating a root-mean-squared value from the plurality of samples in order to obtain each magnitude measurement, the effects of noise and/or jitter on each magnitude measurement may be reduced or eliminated.

In a set of embodiments, estimating the cut-off frequency comprises:
calculating a ratio of the second magnitude measurement to the first magnitude measurement; and
estimating the cut-off frequency by performing a calculation based on the nominal transfer function, using the calculated ratio as an input parameter.

The calculation may be performed by a processor of the radio transceiver. The nominal transfer function may be simplified using algebraic manipulation in order to obtain a simplified version of the transfer function. Such a simplified version of the transfer function may reduce the time required to perform said calculation by reducing the complexity of the operations performed by the processor, albeit potentially at the small expense of accuracy, thus increasing the speed at which the cut-off frequency may be estimated.

In a set of embodiments, estimating the cut-off frequency comprises:
calculating a ratio of the second magnitude measurement to the first magnitude measurement; and
estimating the cut-off frequency using a look-up table stored on a computer-readable storage medium using the calculated ratio as an index, the look-up table comprising a plurality of elements each indicating an estimate of the cut-off frequency for a given ratio.

By using a look-up table in this manner, the time required to estimate the cut-off frequency may be reduced even further, albeit potentially at the small expense of accuracy due to a quantisation error introduced by using the look-up table. In some embodiments, the loss of accuracy due to the use of the look-up table is tolerable, as the reduction in time required to estimate the cut-off frequency is of more benefit than the small loss of accuracy is a detriment.

In a set of embodiments, the look-up table is segmented. The look-up table may be segmented into three portions with each portion covering a predetermined range of ratios at a predetermined resolution. The resolution for higher ratios may be less than the resolution for lower ratios. This reduces the space required in the storage medium to store the look-up table, and further reduces the time required to estimate the cut-off frequency. In a specific example, the look-up table comprises a 3×32 element (i.e. 96 element total) look-up table.

In a set of embodiments, the radio transceiver further comprises a configuration module for storing one or more parameters that configure the operation of the radio transceiver. A value for controlling an automatic gain control (AGC) of the radio transceiver may be stored within the configuration module. The AGC may be locked to maximum gain while performing the method of estimating the cut-off frequency.

The radio-frequency continuous-wave signal may have a signal strength of less than −10 dBm, preferably less than −20 dBm, more preferably less than −50 dBm, yet more preferably less than −65 dBM, e.g. equal to −67 dBm. By configuring the AGC and signal strength of the radio-frequency continuous-wave signal in this manner, saturation at the front end of the receiver circuit portion of the radio transceiver may be reduced and/or prevented while enabling good signal swing.

In a set of embodiments, the filter further comprises an analogue-to-digital converter (ADC) configured to generate samples indicative of an analogue signal magnitude at an output of the filter. The output of the ADC may be used to sample the output of the filter.

In a set of embodiments, the method further comprises calibrating the filter in dependence on the estimated cut-off frequency. Calibrating the filter may comprise adjusting one or more components (e.g. resistors, capacitors, etc.) within the filter. The estimated cut-off frequency may be mapped to a calibration code (which may be stored in the configuration module) which may then be used by the transceiver to adjust one or more components within the filter.

When viewed from a third aspect, the invention provides a method of estimating a cut-off frequency of an electronic filter having a nominal transfer function and a nominal cut-off frequency, the method comprising:
applying a first signal at a first frequency to an input of the filter while sampling an output of the filter in order to obtain a first magnitude measurement, the first frequency being less than the nominal cut-off frequency;
applying a second signal at a second frequency to the input of the filter while sampling the output of the filter in order to obtain a second magnitude measurement, the second frequency being greater than the nominal cut-off frequency; and
estimating the cut-off frequency of the filter based on the nominal transfer function, the first magnitude measurement, and the second magnitude measurement.

In a set of embodiments of the third aspect, the method further comprises:
generating a first and a second modulated synthesised signal by modulating a signal output by a local oscillator with respective first and second modulations;
mixing a radio-frequency continuous-wave signal with the first modulated synthesised signal in order to generate the first signal; and
mixing the radio-frequency continuous-wave signal with the second modulated synthesised signal in order to generate the second signal.

When viewed from a fourth aspect, the invention provides a radio transceiver comprising an electronic filter having a nominal cut-off frequency and a nominal transfer function, the radio transceiver being configured to:
apply a first signal at a first frequency to an input of the filter while sampling an output of the filter in order to obtain a first magnitude measurement, the first frequency being less than the nominal cut-off frequency;
apply a second signal at a second frequency to the input of the filter while sampling the output of the filter in order to obtain a second magnitude measurement, the second frequency being greater than the nominal cut-off frequency; and
estimate a cut-off frequency of the filter based on the nominal transfer function, the first magnitude measurement and the second magnitude measurement.

In a set of embodiments of the fourth aspect, the radio transceiver further comprises a local oscillator, a transmitter circuit portion and a mixer, and is configured to:
generate first and second modulated synthesised signals by modulating a signal output by the local oscillator using the transmitter circuit portion with respective first and second modulations;
mix a radio-frequency continuous-wave signal with the first modulated synthesised signal using the mixer in order to generate the first signal; and
mix the radio-frequency continuous-wave signal with the second modulated synthesised signal using the mixer in order to generate the second signal.

Features of any aspect or embodiment described herein may, wherever appropriate, be applied to any other aspect or embodiment described herein. Features described herein in relation to a method may equally be applied to an apparatus, and vice versa. Where reference is made to different embodiments or sets of embodiments, it should be understood that these are not necessarily distinct but may overlap.

### BRIEF DESCRIPTION OF THE DRAWINGS

One or more non-limiting examples will now be described, by way of example only, with reference to the accompanying figures in which:

FIG. 1 shows a schematic diagram of a radio-frequency transceiver architecture in accordance with an embodiment of the invention;

FIG. 2 shows a schematic diagram of an anti-aliasing filter included in the radio-frequency transceiver shown in FIG. 1;

FIG. 3 shows a flowchart of a method of estimating a cut-off frequency of the anti-aliasing filter shown in FIG. 2 in accordance with an embodiment of the present invention;

FIGS. 4a and 4b each show a graph illustrating a quantisation error introduced by using a non-segmented look-up table in order to estimate the cut-off frequency of the filter;

FIGS. 5a and 5b each show a graph illustrating a quantisation error introduced by using a segmented look-up table in order to estimate the cut-off frequency of the filter.

### DETAILED DESCRIPTION OF THE DRAWINGS

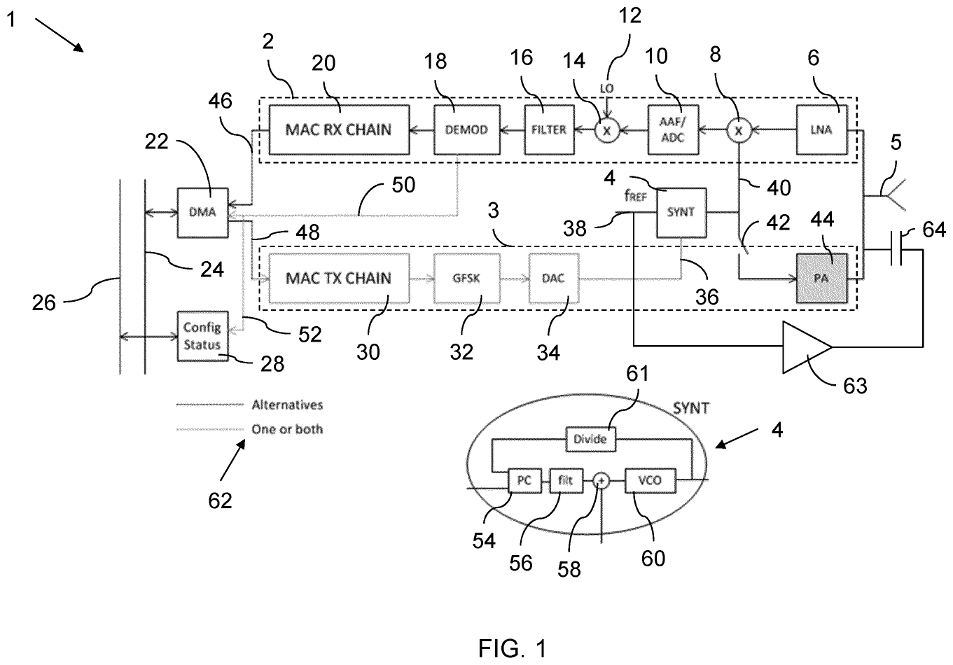

FIG. 1 shows an exemplary RF transceiver circuit portion 1 that is operable to provide filter cut-off frequency estimation using loop back testing in accordance with the invention. In this example, the transceiver circuit portion 1 is used as a Bluetooth™ Low-Energy (BLE) transceiver suitable for Internet-of-Things (IoT) applications. The transceiver circuit portion 1 includes a receiver circuit portion 2, a transmitter circuit portion 3, a frequency synthesiser 4 and a shared antenna 5.

The receiver circuit portion 1 comprises a low noise amplifier 6 (LNA), which receives incoming signals from the antenna 5; followed by an intermediate-frequency (IF) mixer 8; an anti-aliasing filter/analogue-to-digital-converter module 10 (AAF/ADC); a baseband (BB) mixer 14; a filter 16; a demodulator 18; and a receive (RX) MAC chain 20. A local oscillator signal 12, generated by an on-chip oscillator such as a crystal oscillator (not shown), is fed to the BB mixer 14 as one of its inputs.

The transmitter circuit portion 3 comprises a transmit (TX) Media Access Control (MAC) chain 30 followed by a modulator 32—e.g. a digital Gaussian Frequency-shift keying (GFSK) modulator; a digital-to analogue-converter (DAC) 34; and a power amplifier (PA) 44 connected to the antenna 5. The DAC 34 and PA 44 are connected by the synthesiser 4.

The receiver and transmitter circuit portions 2, 3 are connected to a first bus 24 via a Direct Memory Access (DMA) controller 22. A second bus 26 is connected to a configuration module 28 for setting necessary radio parameters—e.g. synthesiser frequency, modulation type, data rate, filter set up, eventual automatic gain control (AGC) settings etc. The transmitter circuit portion 1 (i.e. the output of the MAC RX chain 20) is connected to the DMA 22 via a connection 46, and the receiver circuit portion 3 (i.e. the input of the MAX TX chain 30) is connected to the DMA 22 via another connection 48. Only one of these connections 46, 48 are present or operable at any given time, depending on the mode of operation of the transceiver 1 (see key 62).

An optional additional connection 50 is provided between the demodulator 18 and the DMA 22, and another optional additional connection 52 is provided between the demodulator 18 and the status/configuration module 28. One or both of these connections 50, 52 may be present or operable at any given time, depending on the mode of operation of the transceiver 1 (see key 62).

The transceiver circuit portion 1 has an on-chip frequency synthesiser 4 supplied with a reference signal 38. The reference signal 38 is generated by an on-chip oscillator such as a crystal oscillator (not shown). The reference signal 38 and the local oscillator signal 12 may both be generated by the same on-chip oscillator (not shown).

A shown in the exploded detailed view, the synthesiser 4 comprises a phase-locked loop (PLL) including: a phase comparator 54 for comparing the reference signal 38 with the feedback signal; a low-pass filter 56; a mixer 58 for mixing the modulated signal from the transmitter circuit portion 3 with the PLL; a voltage controlled oscillator (VCO) 60; and a feedback divider 61.

The transmitter circuit portion 3 (i.e. the output of the DAC 34) is connected to the synthesiser via a switch 36. The output of the synthesiser 4 is connected to the IF mixer 8 of the receiver circuit portion 2 via a further switch 40, and to the power amplifier 44 of the transmitter circuit portion 3 via another switch 42. In FIG. 1 the switch 42 is shown as open and the switches 36 & 40 are shown as closed, though it should be understood that each switch 36, 40 & 42 may be selectively opened or closed depending on a mode selection.

An additional circuit portion comprising a buffer 63 and a capacitor 64 in series is provided between the input for the reference signal 38 and the antenna 5. The buffer is selectively enablable in dependence on the operation of the transceiver 1. When enabled, the buffer receives the reference signal 38 from the oscillator (not shown) in order to internally generate a radio-frequency (RF) continuous-wave (CW) signal that is output near to the antenna 5, as will be described in further detail below.

FIG. 1 shows the transceiver 1 operating in a loop back test mode. In this mode, the transmitter circuit portion 3 and receiver circuit portion 2 are connected: the output of the DAC 34 is connected to the synthesiser 4 via the closed switch 36 and the output of the synthesiser 4 is connected to the IF mixer 8 via the closed switch 40. The switch 42 connecting the output of the synthesiser 4 to the power amplifier 44 is opened and the power amplifier 44 is disabled or powered down. Effectively, the transceiver 1 is in RX mode with the transmission path (TX MAC chain 30, modulator 32 and DAC 34) enabled. This means that modulated signals output from the transmitter circuit portion 3, e.g. test packets, may be received and processed at the receiver circuit portion 2 (instead of being amplified and wirelessly transmitted by the antenna 5).

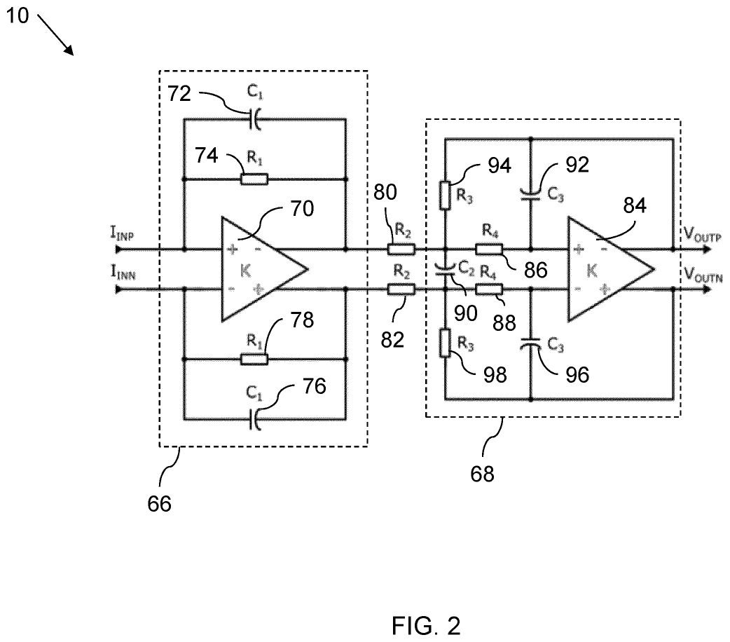

A portion of the AAF 10 is shown in further detail in FIG. 2. The AAF 10 comprises a first filter stage 66 and a second filter stage 68. The first filter stage 66 comprises a first two-line amplifier 70 with a P-line and an N-line. The P-line is provided with a first input current signal I_{INP} and comprises a feedback path comprising a capacitor 72 and a resistor 74 connected in parallel. Similarly, the N-line is provided with a second input current signal I_{INN} and comprises a feedback path comprising a capacitor 76 and a resistor 78 connected in parallel. The P-line output of the amplifier 70 is coupled to the second stage 68 via a resistor 80, and the N-line output of the amplifier 70 is coupled to the second stage 68 via a resistor 82.

The second filter stage 68 comprises a second two-line amplifier 84 with a P-line and an N-line. The P-line input of the second amplifier 84 is coupled to the P-line output of the first amplifier 70 via the resistor 80 and a further resistor 86. Similarly, the N-line input of the second amplifier is coupled to the N-line output of the first amplifier via the resistor 82 and a further resistor 88. The P-line and the N-line are coupled by a capacitor 90 positioned between the resistors 80, 82 and the resistors 86, 88.

The P-line of the second filter stage 68 comprises a feedback path comprising a capacitor 92 and a resistor 94 connected in parallel across the resistor 86. Similarly, the N-line of the second filter stage 68 comprises a feedback path comprising a capacitor 96 and a resistor 98 connected in parallel across the resistor 88. The second amplifier 84 outputs a first voltage signal V_{OUTP} along the P-line output thereof and a second voltage signal V_{OUTN} along the N-line output thereof.

The capacitors 72 & 76 each have a nominal capacitance equal to C₁; the capacitor 92 has a nominal capacitance equal to C₂; and the capacitors 92 & 96 each have a nominal capacitance equal to C₃. The resistors 74 & 78 each have a nominal resistance equal to R₁; the resistors 80 & 82 each have a nominal resistance equal to R₂; the resistors 94 & 98 each have a nominal resistance equal to R₃; and the resistors 86 & 88 each have a nominal resistance equal to R₄.

The AAF 10 shown in FIG. 2 comprises a third-order Butterworth filter which operates as a pure low-pass filter. The first filter stage 66 and the second filter stage 68, when considered in isolation, each operate as a pure low-pass filter. In particular, the first filter stage 66 comprises a first-order RC-stage low-pass filter, and the second filter stage 68 comprises a second-order multiple-feedback (MFB) low-pass filter. As such, the transfer functions of the first and second filter stages 66, 68 are each defined by a single cut-off or pole frequency. The term cut-off frequency, as used herein, is used to describe the input frequency at which the amplitude of the output signal relative to the amplitude of the input signal is attenuated by 3 dB. As such, the cut-off frequency may also be referred to as the −3 dB frequency. The cut-off frequency f_{0,AAF1} of the first filter stage 66 is given by equation (1) below, and the cut-off frequency f_{0,AAF2} of the second filter stage 68 is given by equation (2) below.

$${f}_{0 , AAF 1} = \frac{1}{2 π {R}_{1} {C}_{1}} \qquad ( 1 )$$

$${f}_{0 , AAF 2} = \frac{1}{2 π \sqrt{2 {C}_{2} {C}_{3} {R}_{3} {R}_{4}}} \qquad ( 2 )$$

As the AAF 10 is targeted to be a third-order Butterworth filter, the cut-off frequencies of the first and second filter stages should be equal. Thus, the cut-off frequency of the AAF 10 can be defined by the cut-off frequency of the first filter stage 66 or the second filter stage 68, if the AAF 10 is tuned correctly.

The AAF 10 may be tuned or calibrated to have a desired cut-off frequency by adjusting the characteristics of one or more components therein. For example, the AAF 10 may be tuned or calibrated by tuning the resistances R₁, R₃ & R₄ of the resistors 74, 78, 94, 98, 68 & 88 respectively by equal amounts, thereby impacting the denominators in equations (1) and (2) above by equal amounts. Equally, the AAF 10 may be tuned by tuning the capacitances C₁, C₂ & C₃ of the capacitors 72, 76, 90, 92 & 96 respectively by equal amounts, thereby also impacting the denominators in equations (1) and (2) above by equally amounts. The AAF 10 may equally be tuned by adjusting the characteristics of a combination of the resistances R₁, R₃ & R₄ and the capacitances C₁, C₂ & C₃. In order to tune the AAF 10 to have a desired cut-off frequency, it is necessary to first measure/estimate the cut-off frequency of the AAF 10 in order to determine the tuning required by the AAF 10 in order for it to have a desired cut-off frequency. The embodiment of the present invention set out herein provides a quick and power-efficient method for estimating the cut-off frequency of the AAF 10, which will be described in further detail below.

The first voltage signal V_{OUTP} and the second voltage signal V_{OUTN} are output to an analogue-to-digital converter (ADC), contained within the AAF 10 but not shown in FIG. 2, that converts the voltage signals V_{OUTP} and V_{OUTN} into digital samples and outputs them to the BB mixer 14.

Turning back to FIG. 1, the operation of the synthesiser 4 will now be described in detail. The synthesiser 4 operates in a phase locked loop (PLL). The phase comparator 54 compares a feedback signal from the divider module 61 with the reference signal 38. The phase comparator 54 is followed by a filter 56 (e.g. a low pass filter), the output of which is then mixed with the modulated signal from the transmitter circuit portion at the mixer 58. The mixed signal is fed to the Voltage Controlled Oscillator (VCO) 60. The signal from the VCO 60 enters the PLL again through the divider 61 and is also output from the synthesiser 4. The resulting signal output by the synthesiser 4 comprises the reference frequency 38, modulated by the transmitter circuit portion 3. While the output of the synthesiser 4 may comprise modulated data, which may then be extracted by the receiver circuit portion 2, in this embodiment the data modulated into the signal output by the synthesiser 4 is of no interest. Instead, the modulation provided by the transmitter circuit portion 3 causes the synthesiser 4 to output a synthesised modulated signal at a desired frequency at a given moment in time. The frequency of the modulated synthesised signal output by the synthesiser at any given moment is determined by the modulation provided by the transmitter circuit portion 3.

The transmitter circuit portion 3 is configured to do this as follows: first, the TX MAC chain 30 fetches a sequence of bits via the DMA 20. This is converted into a modulation signal by the modulator 32, which is then converted to an analogue signal by the DAC 34 for driving the synthesiser 4.

A method of estimating the cut-off frequency of the AAF 10 in accordance with the invention will now be described in detail. A radio-frequency (RF) continuous-wave (CW) signal at a given frequency is received by the antenna 5. In some embodiments, the RF CW signal could be received from an external test rig/signal generator (not shown).

In the embodiment illustrated however, the RF CW signal is generated internally by the transceiver 1. The reference signal 38 is routed through the buffer 63 which is connected near the antenna 5 via the capacitor 64. The buffer 63 generates an approximate square wave from the reference signal 38. In some embodiments a small inverter or GPIO pad toggling could be used as the buffer 63 in order to generate the square wave. The resulting square wave is composed of the fundamental sine wave (at the reference frequency) and a wide range of harmonics which are integer multiples of the reference frequency. The capacitor acts as a high-pass filter so that for example at least the 75^{th}, 76^{th} and 77^{th} harmonics of the reference frequency 38 pass through and lower frequencies are filtered out or attenuated by the capacitor. The harmonics provide the RF CW signal which would otherwise be supplied by the external test rig/signal generator. If the reference frequency is at 32 MHz, then the 76^{th} harmonic of the square wave, will reach 2432 MHz—i.e. a sufficient frequency level to be used as a substitute for an RF signal received from an external test rig/signal generator.

The method of estimating the cut-off frequency f_{C} of the AAF 10 is the same regardless of whether the RF CW signal received at the antenna 5 is internally or externally generated. It is preferred that the CW signal is applied at −67 dBm, and that the automatic gain control (AGC) of the transceiver 1, determined by parameters set in the configuration module 28, is locked to maximum gain. This configuration enables good signal swing without saturating the front-end LNA 6.

The received CW signal is fed as an input to the LNA 6. The LNA 6 amplifies the signal while introducing minimal noise, and outputs the amplified RF CW signal to the IF mixer 8. The IF mixer 8 mixes the amplified RF CW signal received from the LNA 6 and the synthesised signal output by the synthesiser 4. The resultant signal output by the IF mixer 8 is therefore an IF signal, the frequency f_{IF} of which is determined by the frequency f_{CW} of the RF CW signal received at the antenna 5 and the frequency f_{synth} of the synthesised signal output by the synthesiser 4. The frequency f_{IF} of the signal output by the IF mixer 8 is given by equation (3) below.

$${f}_{IF} = {f}_{CW} - {f}_{synth} \qquad ( 3 )$$

By modifying the frequency f_{synth} of the synthesised signal output by the synthesiser 4, the frequency f_{IF} of the signal output by the IF mixer 8 may be modified so as to test the frequency response of the AAF 10. It will be appreciated that the frequency f_{CW} of the RF CW signal received at the antenna 5 may equally be modified instead of the frequency f_{synth} of the synthesised signal output by the synthesiser 4 in order to modify the frequency f_{IF} of the signal output by the IF mixer 8, though the description of this is omitted herein for the sake of brevity.

The nominal transfer function (in terms of magnitude) of an n^{th}-order low-pass filter, such as the AAF 10 which is a third-order Butterworth filter in this example, is given by equation (4) below, where f is the input frequency and f_{C} is the cut-off frequency.

$$\vert {H}^{2} ( f ) \vert = \frac{1}{1 + {( \frac{f}{{f}_{C}} )}^{2 n}} \qquad ( 4 )$$

It follows that the attenuation factor (i.e. the ratio) between the squares of two magnitude measurements taken at different input frequencies f₁ and f₂ is given by equation (5) below, where H₀ is the magnitude of the output of the AAF 10 (for DC (i.e. where the input frequency is equal to zero).

$$\frac{\vert {H}^{2} ( {f}_{1} ) \vert}{\vert {H}^{2} ( {f}_{2} ) \vert} = \frac{( \frac{{H}_{0}}{1 + {( \frac{{f}_{1}}{{f}_{C}} )}^{2 n}} )}{( \frac{{H}_{0}}{1 + {( \frac{{f}_{2}}{{f}_{C}} )}^{2 n}} )} \qquad ( 5 )$$

The input frequency f₁ in equations (4) and (5) above comprises the frequency f_{IF} of a first IF CW signal output by the IF mixer 8. The input frequency f₂ in equations (4) and (5) above comprises the frequency f_{IF} of a second IF CW signal output by the IF mixer 8. Thus, the frequencies f₁ and f₂ can be controlled to desired values by the transmitter circuit portion 3 by controlling the frequency f_{synth} of the synthesised signal output by the synthesiser 4.

When f₁<<f_{C}—i.e. the input frequency f₁ is much smaller than the cut-off frequency f_{C}—the nominal transfer function |H²(f₁)| can be approximated as |H²(f₁)|≈|H²(0)|=H₀. Thus, equation (5) simplifies to equation (6) below.

$$\frac{\vert {H}^{2} ( {f}_{1} ) \vert}{\vert {H}^{2} ( {f}_{2} ) \vert} = 1 + {( \frac{{f}_{2}}{{f}_{C}} )}^{2 n} \qquad ( 6 )$$

The ratio between a first root-mean-squared (RMS) magnitude measurement of the filter output |H(f₁)| at the input frequency f₁, and a second RMS magnitude measurement of the filter output |H(f₂)| at the input frequency f₂, is equal to a constant attenuation factor C. Equation (6) therefore simplifies to equation (7) below.

$${C}^{2} = 1 + {( \frac{{f}_{2}}{{f}_{C}} )}^{2 n} \qquad ( 7 )$$

Rearranging equation (7) gives equation (8) below.

$$\frac{{f}_{C}}{{f}_{2}} = \frac{1}{\sqrt[2 n]{{C}^{2} - 1}} \qquad ( 8 )$$

Thus, when f₁ is controlled to be much less than the cut-off frequency f_{C} (i.e. f₁<<f_{c}), the actual cut-off frequency f_{C} of the AAF 10 can be calculated using the second IF input frequency f₂ and the ratio (which is given by the attenuation factor C) of the RMS measurements of the magnitudes of the filter output at the two input frequencies f₁ and f₂. Equation (8) above can therefore be used to calculate an estimate of the cut-off frequency of the AAF 10. Performing the calculation given in equation (8) above, however, can be both complicated and time consuming for a processor to perform.

When f₂<<f_{C} (i.e. the input frequency f₂ is much larger than the cut-off frequency f_{C}), C<<1, as can be seen from equation (7) above. Equation (8) therefore simplifies to equation (9) below.

$$\frac{{f}_{C}}{{f}_{2}} = \frac{1}{\sqrt[n]{C}} \qquad ( 9 )$$

Equation (9) can be visually interpreted as approximating the nominal transfer function of an n^{th} order low-pass or Butterworth filter to two straight lines—one in the passband region and one in the cut-off region, and calculating where the lines intersect. The point of intersection gives a good estimate of the cut-off frequency f_{C}. Using the simplified equation (9) above in order to calculate an estimate of the cut-off frequency f_{C} requires substantially less complex computation by a processor than using equation (8) above. For example, it has been found through experimentation that estimating the cut-off frequency f_{C} using equation (8) above requires approximately 3.4 μs for an exemplary processor with floating-point unit capability, and 60.6 μs for an exemplary processor without floating-point unit capability. On the other hand, estimating the cut-off frequency f_{C} using the simplified equation (9) above requires approximately 2.6 μs for the processor with floating-point unit capability, and 38.2 μs for the processor without floating-point unit capability.

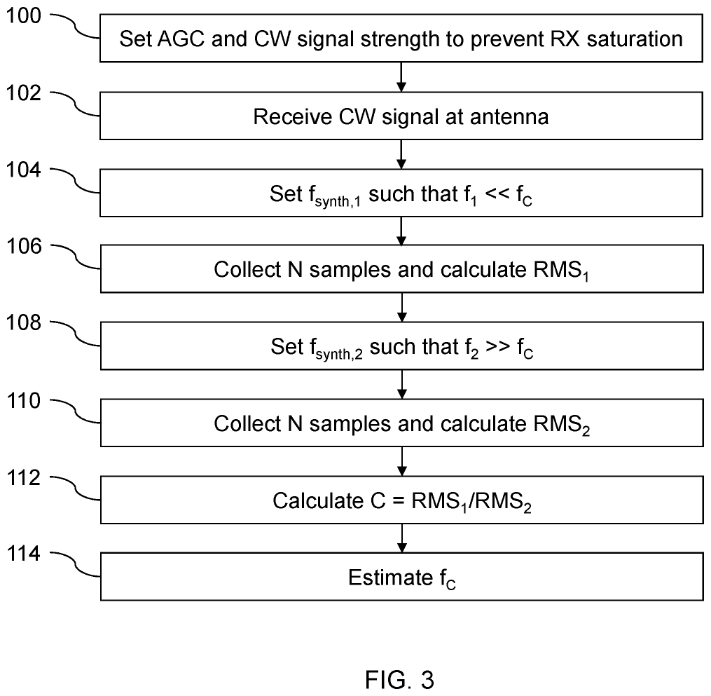

FIG. 3 shows a flowchart of a method of estimating the cut-off frequency f_{C} of the AAF 10 in accordance with an embodiment of the invention. At step 100, the AGC of the transceiver 1 which is determined by the parameters set in the configuration module 28, and the signal strength of the RF CW signal, are configured so as to prevent saturation of the front-end of the receiver circuit portion 2. As described previously, this may be achieved by having the AGC locked to maximum gain and the RF CW signal be applied at −67 dBm. The RF CW signal may be externally generated by a test rig/signal generator, or internally generated as described previously.

At step 102, the RF CW signal is received at the antenna 5. At step 104, the transmitter circuit portion 3 is used to set the output frequency of the synthesiser 4 equal to f_{synth,1}. The frequency f_{synth,1} is chosen in dependence on the frequency f_{CW} of the RF CW signal such that the frequency f_{IF} of the signal output by the IF mixer 8 is equal to f₁, where f₁<<f_{C}. In this case, the cut-off frequency f_{C} of the AAF 10 is not known exactly, but the approximate range of values it could be equal to are known. Typically, the AAF 10 is designed and manufactured to have a specific nominal cut-off frequency f_{C,nom}, but depending on process and temperature variations the cut-off frequency f_{C} of the AAF 10 may exhibit variations of ±30-40% of this nominal value f_{C,nom}. For the purposes of step 104, the cut-off frequency f_{C} of the AAF 10 is assumed to be equal to the nominal value f_{C,nom}.

At step 106, N samples are taken of the output of the ADC contained within the AAF 10. Preferably, N is suitably large so as to be statistically valid without being so large that taking the samples requires an excessively long time. Then, the RMS of the N samples is calculated giving a resultant value RMS₁.

At step 108, the transmitter circuit portion 3 is used to set the output frequency of the synthesiser 4 equal to f_{synth,2}. The frequency f_{synth,2} is chosen in dependence on the frequency f_{CW} of the RF CW signal such that the frequency f_{IF} of the signal output by the IF mixer 8 is equal to f₂, where f₂>>f_{C}. At step 110, N samples are taken at the output of the ADC contained within the AAF 10. The number N of samples taken at step 110 may be equal to the number N of samples taken at step 106, though it may equally be different. Then, the RMS of the N samples is calculated giving a resultant value RMS₂.

At step 112, the attenuation factor C is calculated by taking the ratio between the RMS value RMS₁ calculated at step 106 and the RMS value RMS₂ calculated at step 110. At step 114, the cut-off frequency f_{C} of the AAF 10 is estimated. Estimating the cut-off frequency f_{C} at step 114 in this example comprises performing direct calculation using the simplified equation (9) above, taking n to be equal to three and using the attenuation factor C calculated at step 112 and the frequency f₂ selected at step 108 as parameters. In other embodiments, the cut-off frequency f_{C} is estimated using equation (8) above, though this is less computationally efficient as described previously. In other embodiments, the cut-off frequency f_{C} is estimated using a look-up table (LUT), as is described in further detail below.

There are a number of considerations in preparing a suitable LUT for estimating the cut-off frequency f_{C} of the AAF 10. Firstly, the LUT needs to cover, at minimum, a range of possible cut-off frequencies from f_{C,min}=f_{C,nom}/2 to f_{C,max}=2·f_{C,nom}, in order to cover the typical variation of the cut-off frequency f_{C} from the nominal value f_{C,nom} of approximately ±30-40%. However, in order to ensure the cut-off frequency f_{C} can always be estimated using the LUT, an extra margin is added to the range of values covered by the LUT. In particular, an upper limit of f₂≈5·f_{C} is set for the LUT. From equation (8) above, it follows that C=128 corresponds to f₂≈5.04·f_{C} for a third-order Butterworth filter like the AAF 10 in this example.

A reasonable resolution for the attenuation factor C for the LUT is set to be equal to C/4. Thus, a 512-element LUT is required in order to cover the range of cut-off frequencies indicated above, plus some margin, thereby covering a range of 1≤C≤128. It will be appreciated that a similar LUT may be used for e.g. a fourth-order Butterworth filter by similarly using equation (8) above but taking n to be equal to four.

It follows therefore that C=512 corresponds to f₂≈4.88·f_{C} for a fourth-order Butterworth filter. Thus, using the same resolution of C/4, a 2048-element LUT is required in order to cover the range of cut-off frequencies indicated above, plus some margin, for a fourth-order Butterworth filter. This covers a range of 1≤C≤512. However, using a LUT in this manner introduces some level of quantisation error.

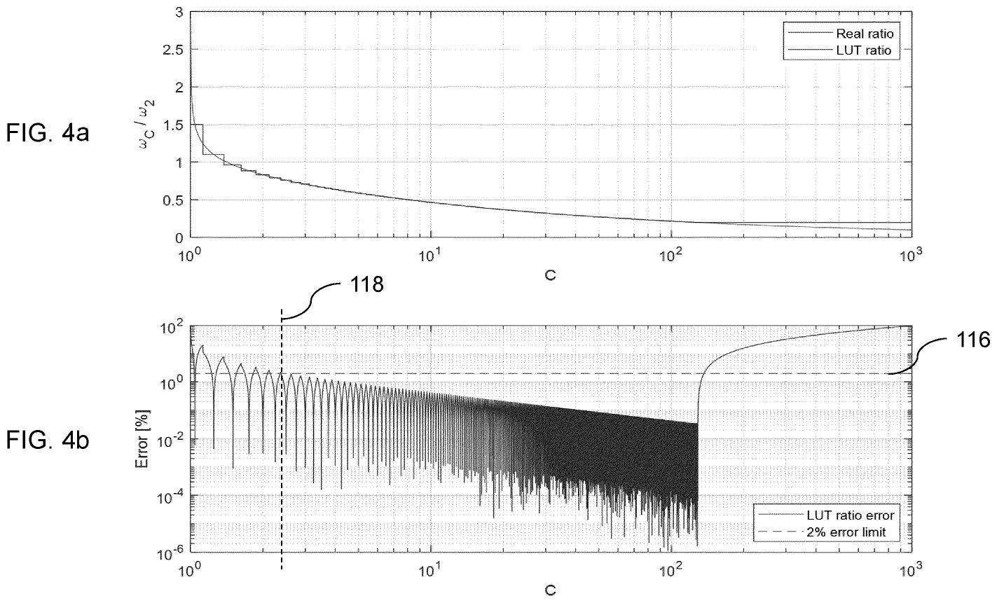

FIG. 4a shows a graph of the attenuation factor C against the ratio f_{C}/f₂, for both the real, theoretical ratio f_{C}/f₂ and the quantised ratio f_{C}/f₂ estimated using the LUT, for a third-order Butterworth filter (i.e. the AAF 10 in this embodiment). FIG. 4b shows a graph of the attenuation factor C against the quantisation error introduced by the LUT estimate for f_{C}/f₂. FIG. 4b also indicates a desired maximum acceptable error 116 of 2%. It will be seen from FIGS. 4a and 4b that the quantisation error introduced by using the LUT is more pronounced for small values of the attenuation factor C than for large values thereof; the error remains below the desired maximum acceptable error 116 for values of C greater than approximately 2.3 (indicated by the line 118). The high quantisation error seen at values greater than 128 is as a result of the LUT in this embodiment being limited to the range 1≤C≤128.

In an embodiment, the LUT is segmented in order to reduce its size. As a result, the amount of storage space required to hold the LUT is reduced, and the time taken for the transceiver 1 to consult the LUT in order to estimate the cut-off frequency f_{C} (by estimating the ratio f_{C}/f₂) is reduced due to a reduced search time. As the quantisation error introduced in estimating the ratio f_{C}/f₂ by using the LUT at small values of C is significantly greater than for large values of C, a smaller resolution for C is required at small values of C than for large values of C. In an embodiment, the LUT for a third-order Butterworth filter (i.e. the AAF 10) is segmented into three portions: a first portion comprising the range C=1 to C=8 with a resolution of C/4; a second portion comprising the range C=9 to C=40 with a resolution of C; and a third portion comprising the range C=41 to C=168 with a resolution of 4C. A 3×32-element (i.e. 96-element total) LUT is required to cover these ranges, with the LUT covering a frequency range of f₂≈0.7·f_{C} to f₂≈5.5·f_{C}.

Similarly, in another embodiment, the LUT for a fourth-order Butterworth filter is segmented into three portions: a first portion comprising the range C=1 to C=8 with a resolution of C/4; a second portion comprising the range C=9 to C=72 with a resolution of 2C; and a third portion comprising the range C=73 to C=584 with a resolution of 16C. A 3×32-element (i.e. 96-element total) LUT is required to cover these ranges, with the LUT covering a frequency range of f₂≈0.7·f_{C} to f₂≈4.88·f_{C}.

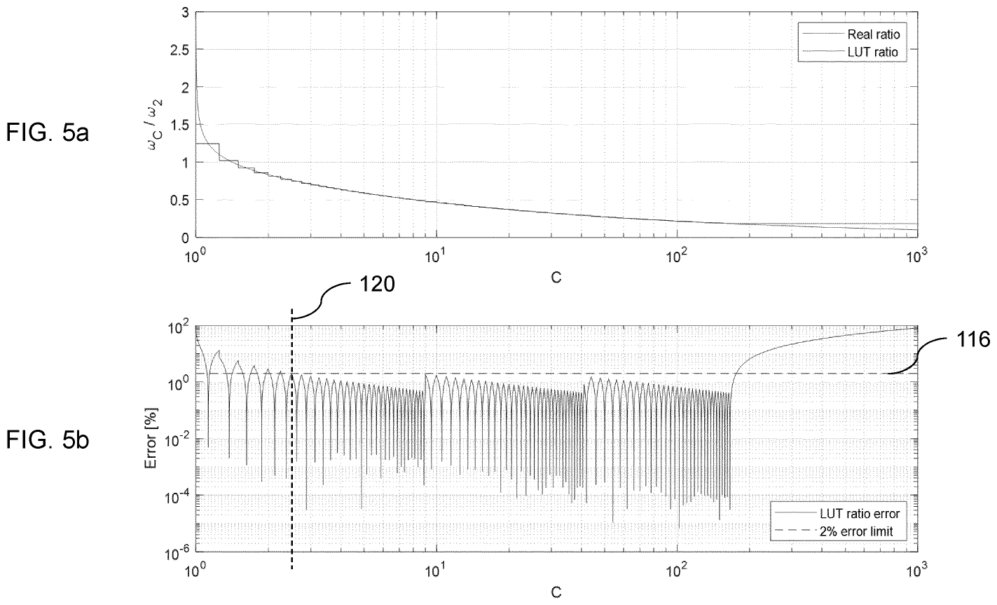

FIG. 5a shows a graph of the attenuation factor C against the ratio f_{C}/f₂, for both the theoretical ratio f_{C}/f₂ and the quantised ratio f_{C}/f₂ estimated using the segmented LUT, for a third-order Butterworth filter (i.e. the AAF 10 in this embodiment). FIG. 5b shows a graph of the attenuation factor C against the quantisation error introduced by the segmented LUT estimate for f_{C}/f₂. As with FIG. 4b, FIG. 5b also indicates the desired maximum acceptable error 116 of 2%. It will be seen from FIGS. 5a and 5b that the quantisation error introduced by the segmented LUT remains below the desired maximum acceptable error 116 for values of C greater than approximately 2.5 (indicated by the line 120), despite the reduced size of the segmented LUT and reduced resolution at higher values of C. Once the cut-off frequency f_{C} of the AAF 10 has been estimated, it may be used calibrate the transceiver 1, particularly the receiver circuit portion 2, in order to compensate for differences between the estimated cut-off frequency f_{C} and the nominal cut-off frequency f_{C,nom} of the AAF 10. Such calibration may be performed using any known techniques including, for example, mapping the estimated cut-off frequency f_{C} to a calibration code which may be stored in the configuration module or another memory (not shown) located elsewhere in the transceiver 1. The calibration code may then be used by the transceiver 1 to adjust the characteristics of one or more components within the AAF 10—e.g. the resistances R₁, R₃ & R₄ and/or capacitances C₁, C₂ & C₃, as described previously.

Thus it will be seen that methods in accordance with the invention enable rapid estimation of the cut-off frequency f_{C} of filters within radio transceivers, particularly the AAF 10 in the transceiver 1. The methods can be performed using a transmitter circuit portion 2 and a receiver circuit portion 3 of a transceiver 1 and utilising only a simple test rig/signal generator configured to output an RF CW signal at only a single frequency (or no test rig at all in embodiments where the RF CW signal is generated internally by the transceiver 1), and thus can be performed post-manufacture (i.e. whilst the transceiver 1 is in the field). Furthermore, methods in accordance with the invention remove the need for e.g. a replica filter to be included in the transceiver 1 in order to estimate the cut-off frequency of a filter, thereby reducing the bill-of-materials and reducing the space required on a system-on-chip (SoC) or printed circuit board (PCB) included in such a transceiver.

It will be appreciated by those skilled in the art that the invention has been illustrated by describing one or more specific embodiments thereof, but is not limited to these embodiments; many variations and modifications are possible within the scope of the appended claims.

1. A method of estimating a cut-off frequency of an electronic filter having a nominal transfer function and a nominal cut-off frequency, the method comprising:
generating a first and a second modulated synthesised signal by modulating a signal output by a local oscillator with respective first and second modulations;
mixing a radio-frequency continuous-wave signal with the first modulated synthesised signal in order to generate a first signal at a first frequency, the first frequency being less than the nominal cut-off frequency;
mixing the radio-frequency continuous-wave signal with the second modulated synthesised signal in order to generate a second signal at a second frequency, the second frequency being greater than the nominal cut-off frequency;
applying the first signal to an input of the filter while sampling an output of the filter in order to obtain a first magnitude measurement;
applying the second signal to the input of the filter while sampling the output of the filter in order to obtain a second magnitude measurement; and
estimating the cut-off frequency of the filter based on the nominal transfer function, the first magnitude measurement, and the second magnitude measurement.

2. The method as claimed in claim 1, wherein the first signal comprises a first intermediate-frequency signal, and the second signal comprises a second intermediate-frequency signal.

3. The method as claimed in claim 1, wherein the radio-frequency continuous-wave signal has a fixed frequency.

4. The method as claimed in claim 1, wherein the electronic filter is included in a radio transceiver, the method further comprising generating the radio-frequency continuous-wave signal externally to the radio transceiver and receiving the radio-frequency continuous-wave signal at an antenna of the radio transceiver.

5. The method as claimed in claim 1, wherein the electronic filter is included in a radio transceiver, the method further comprising the radio transceiver generating the radio-frequency continuous-wave signal internally based on the signal output by the local oscillator of the radio transceiver.

6. The method as claimed in claim 5, wherein generating the radio-frequency continuous-wave signal comprises using a signal converter module to generate, from the signal output from the local oscillator, a test signal comprising a plurality of harmonics of the signal output from the local oscillator, at least one of the plurality of harmonics providing the radio-frequency continuous-wave signal.

7. The method as claimed in claim 1, wherein the filter comprises a low-pass anti-aliasing filter.

8. The method as claimed in claim 1, comprising estimating the cut-off frequency based on a ratio of the second magnitude measurement to the first magnitude measurement.

9. The method as claimed in claim 1, further comprising:
taking a first plurality of samples at the output of the filter while applying the first signal to the input of the filter;
taking a second plurality of samples at the output of the filter while applying the second signal to the input of the filter;
calculating a first root-mean-squared value from the first plurality of samples in order to obtain the first magnitude measurement; and
calculating a second root-mean-squared value from the second plurality of samples in order to obtain the second magnitude measurement.

10. The method as claimed in claim 1, comprising:
calculating a ratio of the second magnitude measurement to the first magnitude measurement; and
estimating the cut-off frequency by performing a calculation based on the nominal transfer function, using the calculated ratio as an input parameter.

11. The method as claimed in claim 1, comprising:
calculating a ratio of the second magnitude measurement to the first magnitude measurement; and
estimating the cut-off frequency using a look-up table stored on a non-transitory computer-readable storage medium using the calculated ratio as an index, the look-up table comprising a plurality of elements each indicating an estimate of the cut-off frequency for a given ratio.

12. The method as claimed in claim 1, further comprising calibrating the filter in dependence on the estimated cut-off frequency.

13. The method as claimed in claim 1, wherein the first frequency is less than 75% of the nominal cut-off frequency and the second frequency is greater than 150% of the nominal cut-off frequency.

14. A radio transceiver comprising a local oscillator, a transmitter circuit portion, a mixer and an electronic filter having a nominal cut-off frequency and a nominal transfer function, the radio transceiver being configured to:
generate first and second modulated synthesised signals by modulating a signal output by the local oscillator using the transmitter circuit portion with respective first and second modulations;
mix a radio-frequency continuous-wave signal with the first modulated synthesised signal using the mixer in order to generate a first signal at a first frequency, the first frequency being less than the nominal cut-off frequency;
mix the radio-frequency continuous-wave signal with the second modulated synthesised signal using the mixer in order to generate a second signal at a second frequency, the second frequency being greater than the nominal cut-off frequency;
apply the first signal to an input of the filter while sampling an output of the filter in order to obtain a first magnitude measurement;
apply the second signal to the input of the filter while sampling the output of the filter in order to obtain a second magnitude measurement; and
estimate a cut-off frequency of the filter based on the nominal transfer function, the first magnitude measurement and the second magnitude measurement.

15. The radio transceiver as claimed in claim 14, wherein the radio transceiver is configured to generate the radio-frequency continuous-wave signal based on the signal output by the local oscillator of the radio transceiver.

16. The radio transceiver as claimed in claim 15, wherein the radio transceiver is configured to generate the radio-frequency continuous-wave signal by using a signal converter module to generate, from a signal output from the local oscillator, a test signal comprising a plurality of harmonics of the signal output from the local oscillator, at least one of the plurality of harmonics providing the radio-frequency continuous-wave signal.

17. The radio transceiver as claimed in claim 14, wherein the filter comprises a low-pass anti-aliasing filter included in a receiver circuit portion of the radio transceiver.

18. The radio transceiver as claimed in claim 14 configured to:
calculate a ratio of the second magnitude measurement to the first magnitude measurement; and
estimate the cut-off frequency by performing a calculation based on the nominal transfer function, using the calculated ratio as an input parameter.

19. The radio transceiver as claimed in claim 14 configured to:
calculate a ratio of the second magnitude measurement to the first magnitude measurement; and
estimate the cut-off frequency using a look-up table stored on a non-transitory computer-readable storage medium using the calculated ratio as an index, the look-up table comprising a plurality of elements each indicating an estimate of the cut-off frequency for a given ratio.

20. The radio transceiver as claimed in claim 14, further configured to calibrate the filter in dependence on the estimated cut-off frequency.

21-22. (canceled)
